(19) United States
(12) Patent Application Publication
(10) Pub. No.: US 2025/0048694 A1
(43) Pub. Date: Feb. 6, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Chung-Hsien YEH, Hsinchu (TW); Chih-Yu MA, Hsinchu (TW); Shih-Chieh CHANG, Taipei City (TW); Sheng-Syun WONG, Hsinchu (TW)

(21) Appl. No.: 18/228,250

(22) Filed: Jul. 31, 2023

(51) Int. Cl. H01L 29/08; H01L 29/06; H01L 29/417; H01L 29/423; H01L 29/66; H01L 29/775

(52) U.S. Cl. CPC H01L 29/0847; H01L 29/0673; H01L 29/41775; H01L 29/42392; H01L 29/66545; H01L 29/66553; H01L 29/775

(57) ABSTRACT

A semiconductor device structure, along with methods of forming such, are described. The structure includes a source/drain epitaxial feature disposed over a substrate, and the source/drain epitaxial feature includes about 0.002 atomic percent to about 0.02 atomic percent of aluminum. The structure further includes a first semiconductor layer in contact with the source/drain epitaxial feature and a gate electrode layer disposed over the first semiconductor layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIGS. 7A-7E are partial cross-sectional side views of various stages of manufacturing the semiconductor device structure taken along line A-A of FIG. 6, in accordance with some embodiments.

FIG. 8 is a perspective view of one of various stages of manufacturing the semiconductor device structure, in accordance with some embodiments.

FIG. 9 is a cross-sectional side view of one of various stages of manufacturing the semiconductor device structure taken along line B-B of FIG. 8, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

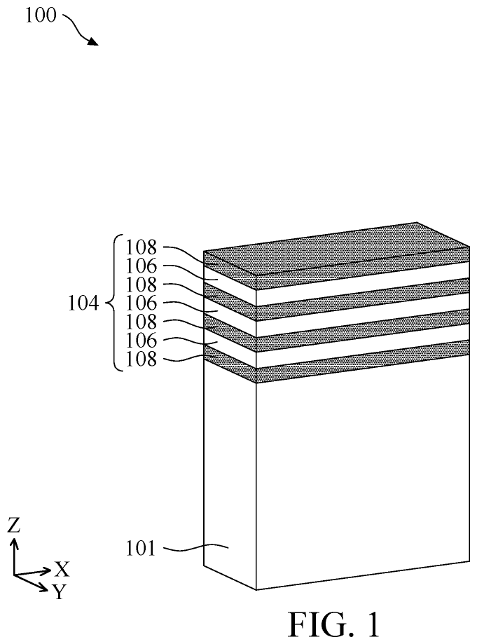

FIGS. 1-9 show sequential processes for manufacturing a semiconductor device structure 100, in accordance with some embodiments. It is understood that additional operations can be provided before, during, and after processes shown by FIGS. 1-9 and some of the operations described below can be replaced or eliminated, for additional embodiments of the method. The order of the operations/processes may be interchangeable.

FIGS. 1-6 are perspective views of various stages of manufacturing a semiconductor device structure, in accordance with some embodiments. As shown in FIG. 1, a stack of semiconductor layers 104 is formed over a substrate 101. The substrate 101 may be a semiconductor substrate. In some embodiments, the substrate 101 includes a crystalline semiconductor layer on at least the surface of the substrate 101. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In this embodiment, the substrate 101 is made of Si. In some embodiments, the substrate 101 is a silicon-on-insulator (SOI) substrate, which includes an insulating layer (not shown) disposed between two silicon layers. In one aspect, the insulating layer is an oxide.

The substrate 101 may include one or more buffer layers (not shown) on the surface of the substrate 101. The buffer layers can serve to gradually change the lattice constant from that of the substrate to that of the source/drain (S/D) regions to be grown on the substrate 101. The buffer layers may be formed from epitaxially grown single crystalline semiconductor materials such as, but not limited to Si, Ge, germanium tin (GeSn), SiGe, GaAs, InSb, GaP, GaSb, InAlAs, InGaAs, GaSbP, GaAsSb, GaN, and InP. In one embodiment, the substrate 101 includes SiGe buffer layers epitaxially grown on the silicon substrate 101. The germanium concentration of the SiGe buffer layers may increase from 30 atomic percent germanium for the bottom-most buffer layer to 70 atomic percent germanium for the top-most buffer layer.

The substrate 101 may include various regions that have been suitably doped with impurities (e.g., p-type or n-type impurities). The dopants are, for example boron for a p-type field effect transistor (FET) and phosphorus for an n-type FET.

The stack of semiconductor layers 104 includes first semiconductor layers 106 and second semiconductor layers 108. The first semiconductor layers 106 and the second semiconductor layers 108 are made of semiconductor materials having different etch selectivity and/or oxidation rates. For example, the first semiconductor layers 106 are made of Si and the second semiconductor layers 108 are made of SiGe. In one aspect, the first semiconductor layers 106 are made of undoped Si. The second semiconductor layers 108 may be doped to enhance etching selectivity against the first semiconductor layers 106. In some embodiments, the stack of semiconductor layers 104 includes alternating first and second semiconductor layers 106, 108, as shown in FIG. 1. The first semiconductor layers 106 or portions thereof may form nanostructure channel(s) of the semiconductor device structure 100 at a later stage. The semiconductor device structure 100 may include a nanostructure transistor. The term nanostructure is used herein to designate any material portion with nanoscale, or even microscale dimensions, and having any suitable shape, such as an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The nanostructure channel(s) of the semiconductor device structure 100 may be surrounded by the gate electrode layer. The nanostructure transistors may be referred to as nanosheet transistors, nanowire transistors, gate-all-around (GAA) transistors, multi-bridge channel (MBC) transistors, or any transistors having the gate electrode layer surrounding the channels. The use of the first semiconductor layers 106 to define a channel or channels of the semiconductor device structure 100 is further discussed below.

It is noted that 3 layers of the first semiconductor layers 106 and 4 layers of the second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104; the number of layers depending on the predetermined number of channels for the semiconductor device structure 100. In some embodiments, the number of first semiconductor layers 106, which is the number of channels, is between 3 and 8.

As described in more detail below, the first semiconductor layers 106 may serve as channels for the semiconductor device structure 100 and the thickness is chosen based on device performance considerations. In some embodiments, each first semiconductor layer 106 has a thickness ranging from about 6 nanometers (nm) to about 12 nm. The second semiconductor layers 108 may eventually be removed and serve to define a vertical distance between adjacent channels for the semiconductor device structure 100 and the thickness is chosen based on device performance considerations. In some embodiments, each second semiconductor layer 108 has a thickness ranging from about 2 nm to about 10 nm.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

A mask structure (not shown) may be formed over the stack of semiconductor layers 104. The mask structure may include an oxygen-containing layer and a nitrogen-containing layer. The oxygen-containing layer may be a pad oxide layer, such as a SiO₂ layer. The nitrogen-containing layer may be a pad nitride layer, such as Si₃N₄. The mask structure may be formed by any suitable deposition process, such as chemical vapor deposition (CVD) process.

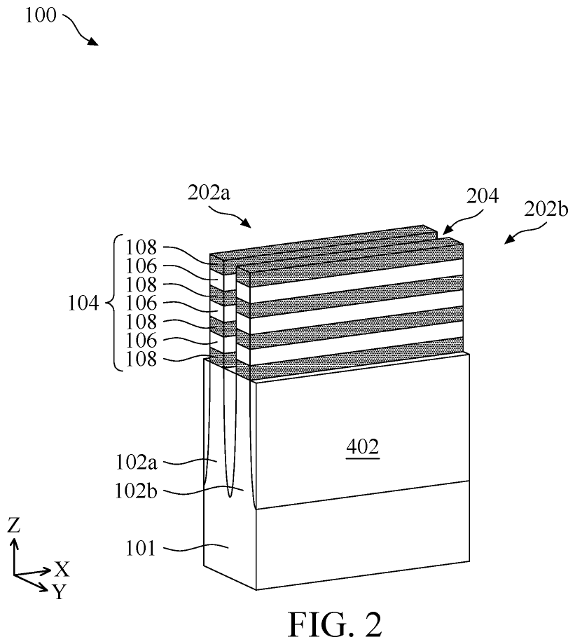

FIG. 2 is a perspective view of one of the various stages of manufacturing the semiconductor device structure 100, in accordance with some embodiments. As shown in FIG. 2, fins 202a and 202b are formed. In some embodiments, each fin 202a, 202b includes a substrate portion 102a. 102b formed from the substrate 101, a portion of the stack of semiconductor layers 104, and a portion of the mask structure 110. The fins 202a, 202b may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins 202a, 202b by etching the stack of semiconductor layers 104 and the substrate 101. The etch process can include dry etch, wet etch, reactive ion etch (RIE), and/or other suitable processes. As shown in FIG. 2, two fins are formed, but the number of the fins is not limited to two.

In some embodiments, the fins 202a, 202b may be fabricated using suitable processes including photolithography and etch processes. The photolithography process may include forming a photoresist layer (not shown) over the mask structure 110, exposing the resist to a pattern, performing post-exposure bake processes, and developing the resist to form a patterned resist. In some embodiments, patterning the resist to form the patterned resist may be performed using an electron beam (e-beam) lithography process. The patterned resist may then be used to protect regions of the substrate 101, and layers formed thereupon, while an etch process forms trenches 204 in unprotected regions through the mask structure 110, the stack of semiconductor layers 104, and into the substrate 101, thereby leaving the extending fins 202a, 202b. The trenches 204 may be etched using a dry etch (e.g., RIE), a wet etch, and/or combination thereof.

As shown in FIG. 2, an insulating material 402 is formed on the substrate 101. The insulating material 402 may be first formed over the substrate 101 so that the fins 202a, 202b are embedded in the insulating material 402. Then, a planarization operation, such as a chemical mechanical polishing (CMP) process and/or an etch-back process, is performed such that the tops of the fins 202a, 202b are exposed from the insulating material 402. Then, the insulating material 402 may be recessed by removing a portion of the insulating material 402 located between adjacent fins 202a, 202b. The recessing of the insulating material 402 may be formed by any suitable process, such as dry etch or wet etch that selectively removes the insulating material 402 but not the semiconductor materials of the first and second semiconductor layers 106, 108. The recessed insulating material 402 may be the shallow trench isolation (STI). The insulating material 402 includes a top surface 504 that may be level with or below a surface of the second semiconductor layers 108 in contact with the substrate portions 102a, 102b of the substrate 101.

The insulating material 402 may be made of an oxygen-containing material, such as silicon oxide or fluorine-doped silicate glass (FSG); a nitrogen-containing material, such as silicon nitride, silicon oxynitride (SION), SiOCN, SiCN; a low-K dielectric material; or any suitable dielectric material. The insulating material 402 may be formed by any suitable method, such as low-pressure chemical vapor deposition (LPCVD), plasma enhanced CVD (PECVD) or flowable CVD (FCVD).

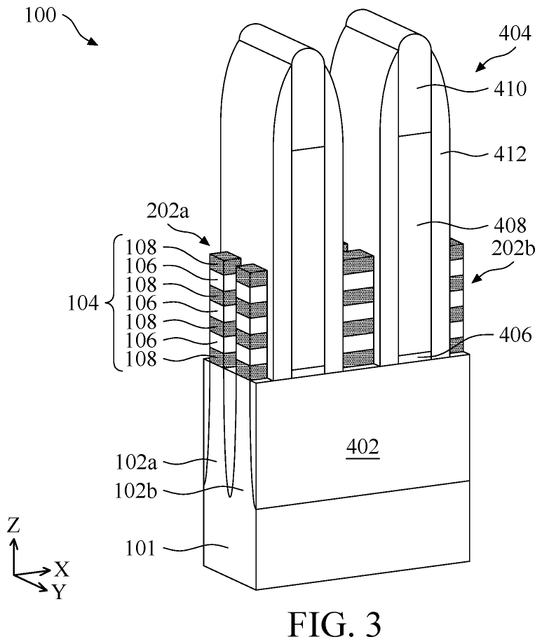

As shown in FIG. 3, one or more sacrificial gate stacks 404 are formed on the semiconductor device structure 100. The sacrificial gate stack 404 may include a sacrificial gate dielectric layer 406, a sacrificial gate electrode layer 408, and a mask structure 410. The sacrificial gate dielectric layer 406 may include one or more layers of dielectric material, such as SiO₂, SiN, a high-K dielectric material, and/or other suitable dielectric material. In some embodiments, the sacrificial gate dielectric layer 406 may be deposited by a CVD process, a sub-atmospheric CVD (SACVD) process, a FCVD process, an ALD process, a PVD process, or other suitable process. The sacrificial gate electrode layer 408 may include polycrystalline silicon (polysilicon). The mask structure 410 may include an oxygen-containing layer and a nitrogen-containing layer.

The sacrificial gate stacks 404 may be formed by first depositing blanket layers of the sacrificial gate dielectric layer 406, the sacrificial gate electrode layer 408, and the mask structure 410, followed by pattern and etch processes. The blanket layers of the sacrificial gate dielectric layer 406, the sacrificial gate electrode layer 408, and the mask structure 410 may be formed by various processes such as CVD (including both LPCVD and PECVD), PVD, ALD, thermal oxidation, e-beam evaporation, or other suitable deposition techniques, or combinations thereof. The pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the sacrificial gate stack 404, the stacks of semiconductor layers 104 of the fins 202a, 202b are partially exposed on opposite sides of the sacrificial gate stack 404. As shown in FIG. 3, two sacrificial gate stacks 404 are formed, but the number of the sacrificial gate stacks 404 is not limited to two. More than two sacrificial gate stacks 404 are arranged along the X direction in some embodiments.

As shown in FIG. 3, a spacer 412 is formed on the sidewalls of the sacrificial gate stacks 404. The spacer 412 may be formed by first depositing a conformal layer that is subsequently etched back to form sidewall spacers 412. For example, a spacer material layer can be disposed conformally on the exposed surfaces of the semiconductor device structure 100. The conformal spacer material layer may be formed by an ALD process. Subsequently, anisotropic etch is performed on the spacer material layer using, for example, RIE. During the anisotropic etch process, most of the spacer material layer is removed from horizontal surfaces, such as the tops of the fins 202a, 202b and the tops of the sacrificial gate stacks 404, leaving the spacers 412 on the vertical surfaces, such as the sidewalls of sacrificial gate stack 404. The spacer 412 may be made of a dielectric material such as silicon oxide, silicon nitride, silicon carbide, silicon oxynitride, SiCN, silicon oxycarbide, SiOCN, and/or combinations thereof. In some embodiments, the spacer 412 includes multiple layers, such as main spacer walls, liner layers, and the like.

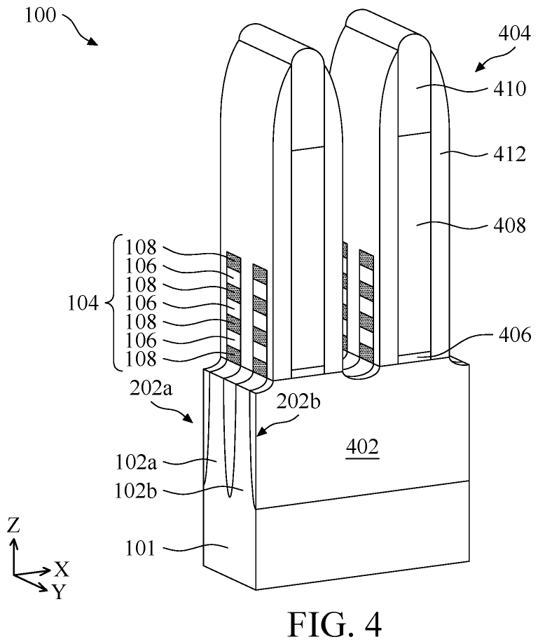

Next, exposed portions of the fins 202a, 202b not covered by the sacrificial gate stacks 404 and the spacers 412 are recessed, as shown in FIG. 4. The recess of the exposed portions of the fins 202a. 202b may be performed by an etch process, such as dry etch, wet etch, or a combination thereof. In some embodiments, exposed portions of the stacks of semiconductor layers 104 of the fins 202a, 202b are removed, exposing portions of the substrate portions 102a. 102b. In some embodiments, a portion of the substrate portions 102a, 102b may be also removed. As shown in FIG. 4, the exposed portions of the fins 202a, 202b are recessed to a level below the top surface of the insulating material 402.

At this stage, end portions of the stacks of semiconductor layers 104 under the sacrificial gate stacks 404 and the spacers 412 have substantially flat surfaces which may be flush with corresponding spacers 412. In some embodiments, the end portions of the stacks of semiconductor layers 104 under the sacrificial gate stacks 404 and spacers 412 are slightly horizontally etched.

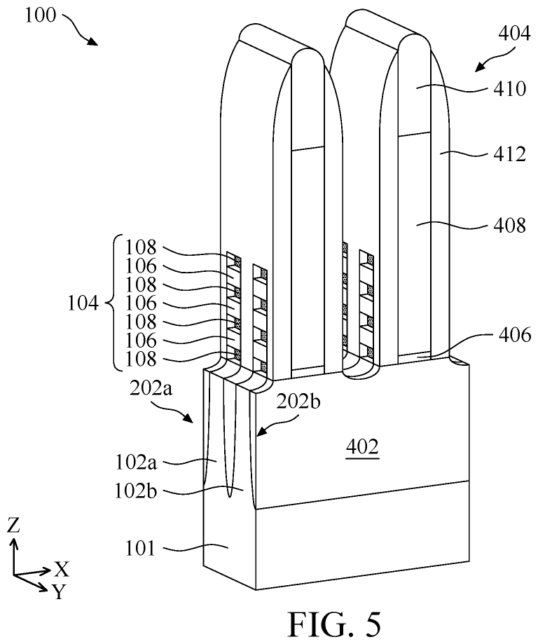

As shown in FIG. 5, the edge portions of each second semiconductor layer 108 are removed, forming gaps 414. In some embodiments, the portions of the second semiconductor layers 108 are removed by a selective wet etch process that does not remove the first semiconductor layers 106. For example, in cases where the second semiconductor layers 108 are made of SiGe, and the first semiconductor layers 106 are made of silicon, a selective wet etch including an ammonia and hydrogen peroxide mixtures (APM) may be used.

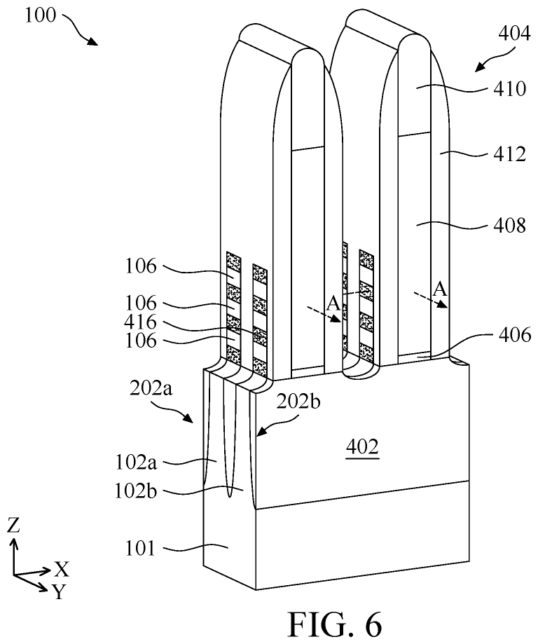

As shown in FIG. 6, dielectric spacers 416 are formed in the gaps 414. In some embodiments, the dielectric spacers 416 may be made of SION, SiCN, SiOC, SiOCN, or SiN. In some embodiments, the dielectric spacers 416 may be formed by first forming a conformal dielectric layer using a conformal deposition process, such as ALD, followed by an anisotropic etch to remove portions of the conformal dielectric layer other than the dielectric spacers 416. The dielectric spacers 416 may be protected by the first semiconductor layers 106 and the spacers 412 during the anisotropic etch process. In some embodiments, the dielectric spacers 416 may be flush with the spacers 412.

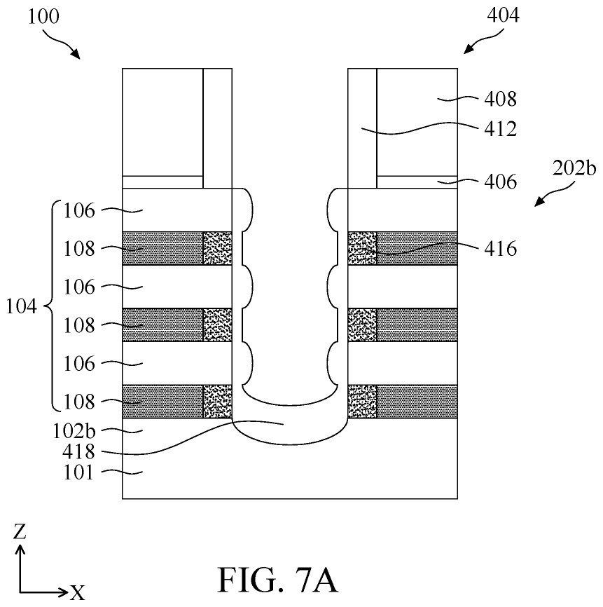

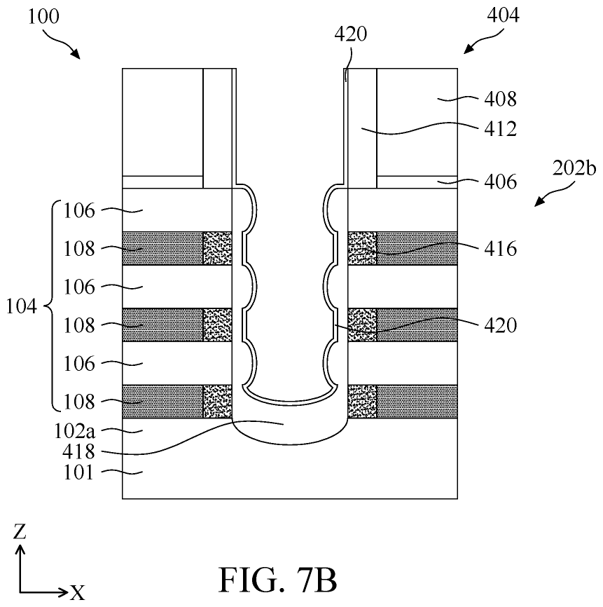

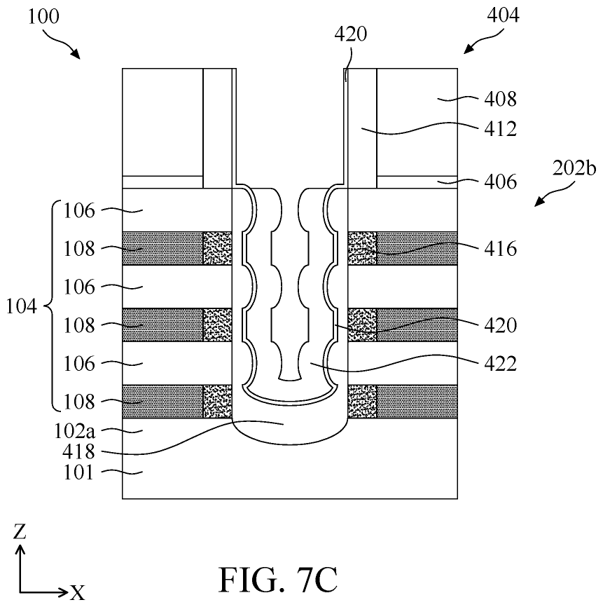

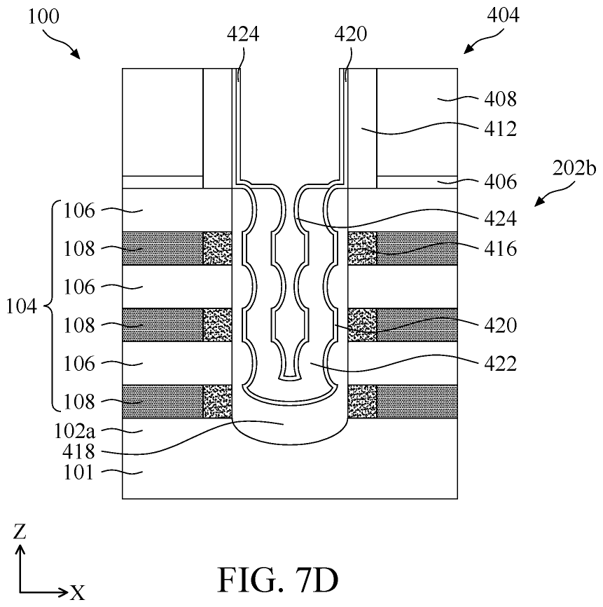

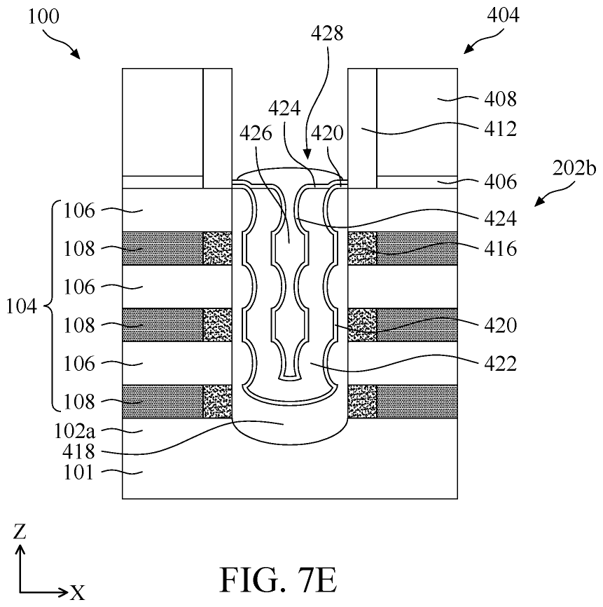

FIGS. 7A to 7E are partial cross-sectional side views of various stages of manufacturing the semiconductor device structure 100 taken along line A-A of FIG. 6, in accordance with some embodiments. Portions of the sacrificial gate stacks 404 and the spacers 412 are shown in FIGS. 7A to 7E for clarity. As shown in FIG. 7A, a first semiconductor material 418 is formed on the exposed substrate portion 102b, the first semiconductor layers 106, and the dielectric spacers 416. The first semiconductor material 418 may be formed by any suitable process, such as epitaxy, for example MBE, MOCVD, and/or other suitable epitaxial growth processes. The first semiconductor material 418 may be grown from the substrate portion 102b and the first semiconductor layers 106. In some embodiments, portions of the first semiconductor material 418 grown from vertically adjacent first semiconductor layers 106 may be connected. As a result, the dielectric spacers 416 are covered by the first semiconductor material 418. In some embodiments, the portions of the first semiconductor material 418 adjacent the first semiconductor layer 106 is thicker than the portions of the first semiconductor material 418 adjacent the dielectric spacers 416. In some embodiments, an n-type epitaxial feature is to be formed, and the first semiconductor material 418 includes Si doped with an n-type dopant, such as As or P. The n-type dopant concentration may range from about 1×10²⁰/cm³ to about 8×10²⁰/cm³. In some embodiments, a p-type epitaxial feature is to be formed, and the first semiconductor material 418 includes SiGe doped with a p-type dopant, such as B. The p-type dopant concentration may range from about 1×10²⁰/cm³ to about 8×10²⁰/cm³. In some embodiments, the first semiconductor material 418 may be SiGe doped with a dopant, and the first semiconductor material 418 has 25 atomic percent to about 45 atomic percent of Ge.

In some embodiments, the n-type epitaxial feature and the p-type epitaxial feature are formed at different times. For example, a sacrificial mask layer (not shown) may be first formed in the n-type FET region, i.e., on the exposed substrate portion and the first semiconductor layers in the region where n-type epitaxial features are to be formed. The sacrificial mask layer may include any suitable dielectric material. After the formation of the p-type epitaxial features in the p-type FET region, the sacrificial mask layer is removed. Another sacrificial mask layer (not shown) is then formed on the p-type epitaxial features in the p-type FET region, and n-type epitaxial features are formed in the n-type FET region. The sacrificial mask layer formed on the p-type epitaxial features is removed after the formation of the n-type epitaxial features. In some embodiments, a sacrificial mask layer (not shown) may be first formed in the p-type FET region, i.e., on the exposed substrate portion and the first semiconductor layers in the region where p-type epitaxial features are to be formed. After the formation of the n-type epitaxial features in the n-type FET region, the sacrificial mask layer is removed. Another sacrificial mask layer (not shown) is then formed on the n-type epitaxial features in the n-type FET region, and p-type epitaxial features are formed in the p-type FET region. The sacrificial mask layer formed on the n-type epitaxial features is removed after the formation of the p-type epitaxial features.

In some embodiments, the process to form the first semiconductor material 418 may utilize a chlorine-containing gas to remove any first semiconductor material 418 formed on surfaces other than semiconductor surfaces, such as on the spacers 412 and the insulating material 402 (FIG. 6). The chlorine-containing gas may be co-flowed with the silicon-containing precursor. As a result, the first semiconductor material 418 is selectively formed on the first semiconductor layers 106, the substrate portion 102a, and the dielectric spacers 416 (as a result of connecting the portions of the first semiconductor material 418 formed on the first semiconductor layers 106).

As shown in FIG. 7B, an aluminum-containing layer 420 is formed on the first semiconductor material 418. In some embodiments, the aluminum-containing layer 420 is a layer of aluminum. In some embodiments, the aluminum-containing layer 420 is a layer of aluminum silicide. The aluminum-containing layer 420 may be formed by any suitable process, such as CVD or PVD. In some embodiments, a DC magnetron sputtering process is performed to form the aluminum-containing layer 420. The aluminum-containing layer 420 is also formed on the dielectric materials, such as the spacers 412 and the insulating material 402 (FIG. 6). In some embodiments, the portion of the aluminum-containing layer 420 formed on the first semiconductor material 418 may be a conformal layer and has a thickness ranging from about 0.2 nm to about 1.5 nm. The portions of the aluminum-containing layer 420 formed on the dielectric surfaces, such as the spacers 412 and the insulating material 402 (FIG. 6), are thinner compared to the portions of the aluminum-containing layer 420 formed on the semiconductor surfaces, because the aluminum-containing layer 420 has a faster deposition rate on the semiconductor surfaces compared to dielectric surfaces. In some embodiments, the portions of the aluminum-containing layer 420 formed on the dielectric surfaces may be discontinuous. The aluminum-containing layer 420 formed on the first semiconductor material 418 may increase the critical dimension (CD) of the S/D epitaxial features and the deposition rate of the subsequently deposited semiconductor materials without creating defects in the S/D epitaxial features. Thus, if the thickness of the aluminum-containing layer 420 is less than about 0.2 nm, the aluminum-containing layer 420 may be too thin to have the above-mentioned benefits. On the other hand, if the thickness of the aluminum-containing layer 420 is greater than about 1.5 nm, the opening between adjacent stacks of semiconductor layers 104 may be filled, and no more semiconductor material may be formed on the aluminum-containing layer 420. As a result, S/D electrical resistance may be increased. Furthermore, in the embodiments where a chlorine-containing gas is co-flowed along with the silicon-containing precursor, the selectivity loss when forming the semiconductor materials of the S/D epitaxial features is improved with the aluminum-containing layer 420.

As shown in FIG. 7C, a second semiconductor material 422 is formed on the portion of the aluminum-containing layer 420 that is formed on the first semiconductor material 418. The second semiconductor material 422 may be formed by epitaxy. In some embodiments, the second semiconductor material 422 is formed by the same process as the first semiconductor material 418. The second semiconductor material 422 may include Si doped with an n-type dopant for an n-type epitaxial feature or SiGe doped with a p-type dopant for a p-type epitaxial feature. For example, the second semiconductor material 422 may be SiGe doped with a dopant, and the second semiconductor material 422 has 40 atomic percent to about 60 atomic percent of Ge. In some embodiments, the second semiconductor material 422 has a higher germanium atomic percentage than the first semiconductor material 418. In some embodiments, the dopant concentration of the second semiconductor material 422 may range from about 5×10²⁰/cm³ to about 4×10²¹/cm³. In some embodiments, the second semiconductor material 422 has a higher dopant concentration than the first semiconductor material 418.

The aluminum-containing layer 420 increases the CD and deposition rate of the second semiconductor material 422. The CD along the X direction is limited by the opening between the adjacent stacks of semiconductor layers 104. However, the CD along the Y direction is increased compared to a semiconductor material formed without the aluminum-containing layer 420. In some embodiments, the second semiconductor material 422 may be initially formed on the portion of the aluminum-containing layer 420 formed on the dielectric surfaces, such as the spacers 412. As described above, by co-flowing the chlorine-containing gas with the silicon-containing precursor, the portion of the second semiconductor material 422 formed on the portion of the aluminum-containing layer 420 formed on the dielectric surfaces may be removed during the formation of the second semiconductor material 422.

As shown in FIG. 7D, a second aluminum-containing layer 424 is formed on the second semiconductor material 422. The second aluminum-containing layer 424 may include the same material as the first aluminum-containing layer 420 and may be formed by the same process as the first aluminum-containing layer 420. In some embodiments, portions of the second aluminum-containing layer 424 is formed on the portions of the first aluminum-containing layer 420 that are formed on the dielectric surfaces, such as the spacers 412, as shown in FIG. 7D. Similar to the first aluminum-containing layer 420, the portion of the second aluminum-containing layer 424 formed on the first aluminum-containing layer 420 may be thinner due to the thin or discontinuous portions of the first aluminum-containing layer 420 formed on the dielectric surfaces. Thus, in some embodiments, the portion of the second aluminum-containing layer 424 formed on the first aluminum-containing layer 420 has a thickness less than a thickness of the portion of the second aluminum-containing layer 424 formed on the second semiconductor material 422. In some embodiments, the combined thickness of the portions of the first and second aluminum-containing layers 420, 424 formed on the spacer 412 is substantially greater than the thickness of the portions of the first or second aluminum-containing layers 420, 424 formed on the first and second semiconductor materials 418, 422, but is substantially less than the sum of the thicknesses of the portions of the first and second aluminum-containing layers 420, 424 formed on the first and second semiconductor materials 418, 422.

As shown in FIG. 7E, a third semiconductor material 426 is formed on the second aluminum-containing layer 424. The third semiconductor material 426 may be formed by epitaxy. The third semiconductor material 426 may include doped Si for an n-type epitaxial feature or doped SiGe for a p-type epitaxial feature. For example, the third semiconductor material 426 may be doped SiGe having 45 atomic percent to about 55 atomic percent of Ge. In some embodiments, the dopant concentration of the third semiconductor material 426 may range from about 1×10²¹/cm³ to about 2×10²¹/cm³. In some embodiments, the dopant concentration of the third semiconductor material 426 is substantially less than the dopant concentration of the second semiconductor material 422. The first, second, and third semiconductor materials 418, 422, 426 and the first and second aluminum-containing layers 420, 424 together may be referred to as a S/D epitaxial feature 428, which may be an n-type epitaxial feature or a p-type epitaxial feature. The S/D epitaxial features 428 may be the S/D regions. In this disclosure, a source and a drain are interchangeably used, and the structures thereof are substantially the same. Furthermore, source/drain region(s) may refer to a source or a drain, individually or collectively dependent upon the context.

As shown in FIG. 7E, the third semiconductor material 426 fills the opening between adjacent stacks of semiconductor layers 104. The third semiconductor material 426 is also formed over the horizontal portions of the first and second aluminum-containing layers 420, 424 adjacent to the spacers 412, as shown in FIG. 7E. After the formation of the third semiconductor material 426, the exposed portions of the first and second aluminum-containing layers 420, 424 formed on the dielectric surfaces may be removed. In some embodiments, a plasma process is performed to remove the exposed portions of the first and second aluminum-containing layers 420, 424. The plasma process may utilize a hydrogen-containing plasma, which selectively removes the exposed first and second aluminum-containing layers 420, 424. The third semiconductor material 426 and the dielectric materials of the spacers 412, the insulating material 402, and the mask structure 410 are not substantially affected by the plasma process.

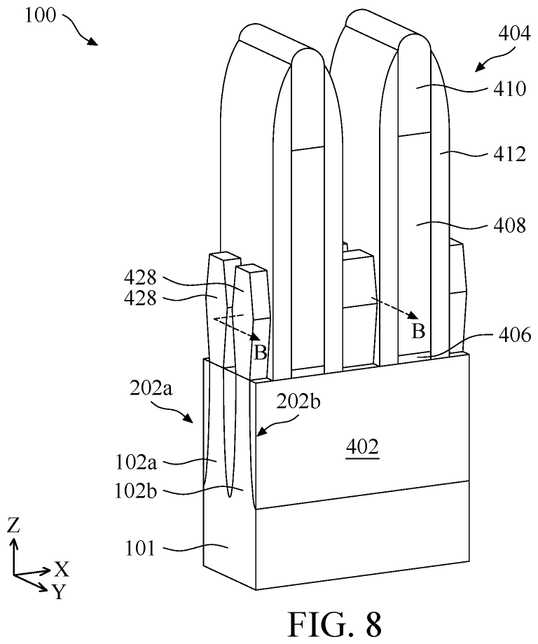

FIG. 8 is a perspective view of the semiconductor device structure 100 shown in FIG. 7E, in accordance with some embodiments. As shown in FIG. 8, the S/D epitaxial features 428, which includes the first, second, and third semiconductor materials 418, 422, 426 and the first and second aluminum-containing layers 420, 424, are formed on the substrate portions 102a, 102b of the fins 202a, 202b. In some embodiments, the S/D epitaxial feature 428 includes both aluminum-containing layers 420, 424. In some embodiments, each S/D epitaxial feature 428 includes one of the aluminum-containing layers 420, 424. In some embodiments, each S/D epitaxial feature 428 includes about 0.002 atomic percent to about 0.02 atomic percent of aluminum. If the S/D epitaxial feature 428 includes less than about 0.002 atomic percent of aluminum, the CD of the S/D epitaxial feature 428 may not be increased and the deposition time of the S/D epitaxial feature 428 may not be shortened. On the other hand, if the S/D epitaxial feature 428 includes more than about 0.02 atomic percent of aluminum, S/D electrical resistance may be increased. With the aluminum-containing layer 420 and/or the aluminum-containing layer 424, the CD of the S/D epitaxial feature 428 along the Y direction is increased. In some embodiments, the CD of the S/D epitaxial feature 428 along the Y direction is increased from about 35 nm to about 45 nm. Furthermore, the deposition time of the S/D epitaxial feature 428 is shortened.

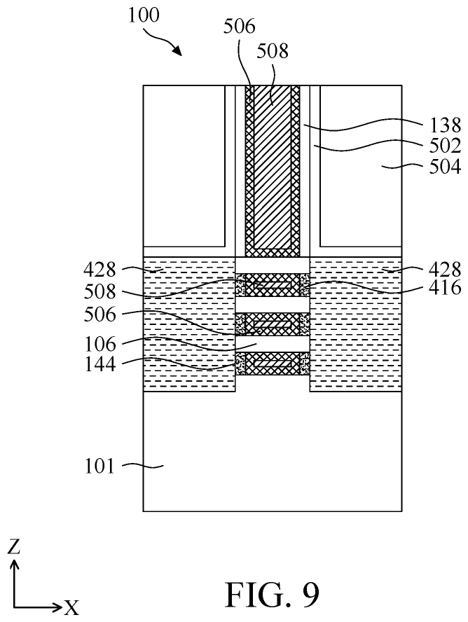

FIG. 9 is a cross-sectional side view of one of various stages of manufacturing the semiconductor device structure 100 taken along line B-B of FIG. 8, in accordance with some embodiments. The details of the S/D epitaxial features 428 are omitted for clarity. Subsequent processes may be performed to complete the semiconductor device structure 100. For example, a contact etch stop layer (CESL) 502 may be formed on the S/D epitaxial features 428, and an interlayer dielectric (ILD) layer 504 may be formed on the CESL. The CESL 502 may include an oxygen-containing material or a nitrogen-containing material, such as silicon nitride, silicon carbon nitride, silicon oxynitride, carbon nitride, silicon oxide, silicon carbon oxide, the like, or a combination thereof. The CESL 502 may be formed by CVD, PECVD, ALD, or any suitable deposition technique. In some embodiments, the CESL 502 is a conformal layer formed by the ALD process. The materials for the ILD layer 504 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 504 may be deposited by a PECVD process or other suitable deposition technique. In some embodiments, after formation of the ILD layer 504, the semiconductor device structure 100 may be subject to a thermal process to anneal the ILD layer 504.

Then, the sacrificial gate stacks 404 and the second semiconductor layers 108 are removed, and a gate dielectric layer 506 and a gate electrode layer 508 are formed to surround exposed portions of the first semiconductor layers 106. The sacrificial gate electrode layer 408 may be first removed by any suitable process, such as dry etch, wet etch, or a combination thereof, followed by the removal of the sacrificial gate dielectric layer 406, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 408. The removal of the second semiconductor layers 108 exposes the dielectric spacers 1402 and the first semiconductor layers 106. The removal of the second semiconductor layers 108 may be performed by any suitable processes, such as dry etch, wet etch, or a combination thereof. The etch process may be a selective etch process. In some embodiments, the gate dielectric layer 506 includes a high-K dielectric material. The gate dielectric layers 506 may be formed by any suitable processes, such as ALD processes. In some embodiments, the gate dielectric layers 506 are formed by conformal processes. The gate electrode layer 508 is formed on the gate dielectric layer 506 to surround a portion of each first semiconductor layer 106. The gate electrode layer 508 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layers 506 may be formed by PVD, CVD, ALD, electro-plating, or other suitable method.

The present disclosure provides a semiconductor device structure 100 including one or more aluminum-containing layers 420, 424 in the S/D epitaxial feature 428. Some embodiments may achieve advantages. For example, the aluminum-containing layers 420, 424 may lead to increased CD and faster deposition time.

An embodiment is a semiconductor device structure. The semiconductor device structure includes a source/drain epitaxial feature disposed over a substrate, and the source/drain epitaxial feature includes about 0.002 atomic percent to about 0.02 atomic percent of aluminum. The structure further includes a first semiconductor layer in contact with the source/drain epitaxial feature and a gate electrode layer disposed over the first semiconductor layer.

Another embodiment is a semiconductor device structure. The semiconductor device structure includes a source/drain epitaxial feature having a first semiconductor material, a first aluminum-containing layer disposed on the first semiconductor material, and a second semiconductor material disposed on the first aluminum-containing layer. The structure further includes a first semiconductor layer in contact with the source/drain epitaxial feature and a gate electrode layer disposed over the first semiconductor layer.

A further embodiment is a method. The method includes forming a stack of first and second semiconductor layers, forming a sacrificial gate stack over a portion of the stack of first and second semiconductor layers, forming spacers on sidewalls of the sacrificial gate stack, removing exposed portions of the stack of first and second semiconductor layers to expose a substrate portion, depositing a first semiconductor material over the substrate portion and in contact with the first semiconductor layers, and depositing a first aluminum-containing layer. The first aluminum-containing layer has a first portion disposed on the first semiconductor material and a second portion disposed on the spacers. The method further includes depositing a second semiconductor material on the first portion of the first aluminum-containing layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a source/drain epitaxial feature disposed over a substrate, wherein the source/drain epitaxial feature comprises about 0.002 atomic percent to about 0.02 atomic percent of aluminum;
a first semiconductor layer in contact with the source/drain epitaxial feature; and
a gate electrode layer disposed over the first semiconductor layer.

2. The semiconductor device structure of claim 1, further comprising a second semiconductor layer in contact with the source/drain epitaxial feature and a third semiconductor layer in contact with the source/drain epitaxial feature, wherein the second semiconductor layer is disposed over the first semiconductor layer, and the third semiconductor layer is disposed over the second semiconductor layer.

3. The semiconductor device structure of claim 2, further comprising dielectric spacers disposed between the first and second semiconductor layers and between the second and third semiconductor layers.

4. The semiconductor device structure of claim 3, wherein the gate electrode layer is disposed between the first and second semiconductor layers and between the second and third semiconductor layers.

5. The semiconductor device structure of claim 1, further comprising a gate dielectric layer disposed over the first semiconductor layer, wherein the gate electrode layer is disposed on the gate dielectric layer.

6. A semiconductor device structure, comprising:
a source/drain epitaxial feature, comprising:
a first semiconductor material;
a first aluminum-containing layer disposed on the first semiconductor material; and
a second semiconductor material disposed on the first aluminum-containing layer;
a first semiconductor layer in contact with the source/drain epitaxial feature; and
a gate electrode layer disposed over the first semiconductor layer.

7. The semiconductor device structure of claim 6, wherein the first aluminum-containing layer comprises aluminum or aluminum silicide.

8. The semiconductor device structure of claim 6, wherein the first aluminum-containing layer has a thickness ranging from about 0.2 nm to about 1.5 nm.

9. The semiconductor device structure of claim 6, wherein the source/drain epitaxial feature further comprises a second aluminum-containing layer disposed on the second semiconductor material and a third semiconductor material disposed on the second aluminum-containing layer.

10. The semiconductor device structure of claim 9, wherein a portion of the first aluminum-containing layer is disposed on a top surface of the first semiconductor material.

11. The semiconductor device structure of claim 10, wherein a portion of the second aluminum-containing layer is disposed on the portion of the first aluminum-containing layer and a top surface of the second semiconductor material.

12. The semiconductor device structure of claim 11, wherein the third semiconductor material is disposed on the portion of the first aluminum-containing layer and the portion of the second aluminum-containing layer.

13. A method, comprising:
forming a stack of first and second semiconductor layers;
forming a sacrificial gate stack over a portion of the stack of first and second semiconductor layers;
forming spacers on sidewalls of the sacrificial gate stack;
removing exposed portions of the stack of first and second semiconductor layers to expose a substrate portion;
depositing a first semiconductor material over the substrate portion and in contact with the first semiconductor layers;
depositing a first aluminum-containing layer, wherein the first aluminum-containing layer has a first portion disposed on the first semiconductor material and a second portion disposed on the spacers; and
depositing a second semiconductor material on the first portion of the first aluminum-containing layer.

14. The method of claim 13, wherein a thickness of the first portion of the first aluminum-containing layer is substantially greater than a thickness of the second portion of the first aluminum-containing layer.

15. The method of claim 14, wherein the thickness of the first portion of the first aluminum-containing layer ranges from about 0.2 nm to about 1.5 nm.

16. The method of claim 13, further comprising depositing a second aluminum-containing layer, wherein the second aluminum-containing layer has a first portion disposed on the second semiconductor material and a second portion disposed on the second portion of the first aluminum-containing layer.

17. The method of claim 16, further comprising depositing a third semiconductor material on the first portion of the second aluminum-containing layer.

18. The method of claim 17, further comprising removing the second portion of the first aluminum-containing layer and the second portion of the second aluminum-containing layer.

19. The method of claim 18, wherein the second portion of the first aluminum-containing layer and the second portion of the second aluminum-containing layer are removed by a plasma process.

20. The method of claim 19, wherein the plasma process utilizes a hydrogen plasma.
